(19) United States
(12) Patent Application Publication
(10) Pub. No.: US 2009/0053861 A1
(43) Pub. Date: Feb. 26, 2009

(54) METHOD FOR FABRICATING PIXEL STRUCTURE

(75) Inventors: Chin-Yueh Liao, Hsinchu (TW); Chih-Chun Yang, Hsinchu (TW); Ming-Yuan Huang, Hsinchu (TW); Han-Tu Lin, Hsinchu (TW); Chih-Hung Shih, Hsinchu (TW); Ta-Wen Liao, Hsinchu (TW); Chia-Chi Tsai, Hsinchu (TW)

Correspondence Address: JIANQ CHYUN INTELLECTUAL PROPERTY OFFICE, 7 FLOOR-1, NO. 100, ROOSEVELT ROAD, SECTION 2, TAIPEI, 100, TW

(73) Assignee: AU OPTRONICS CORPORATION, Hsinchu (TW)

(21) Appl. No.: 12/040,914

(22) Filed: Mar. 2, 2008

(30) Foreign Application Priority Data
Aug. 21, 2007 (TW) 96130855

(51) Int. Cl. H01L 21/336

(52) U.S. Cl. 438/155; 257/E21.411

(57) ABSTRACT

A method for fabricating a pixel structure is provided. A substrate is provided, and a gate is formed on the substrate. A gate dielectric layer covering the gate is formed on the substrate. A semiconductor layer is formed on the gate dielectric layer. A first shadow mask exposing parts of the semiconductor layer is provided above the semiconductor layer. A laser is irradiated on the semiconductor layer through the first shadow mask to remove parts of semiconductor layer and form a channel layer. A source and a drain are respectively formed on the channel layer at both sides of the gate. A patterned passivation layer which covers the channel layer and exposes the drain is formed. A conductive layer is formed to cover the patterned passivation layer and the drain. The conductive layer is automatically patterned by the patterned passivation layer to form a pixel electrode.

### CROSS-REFERENCE TO RELATED APPLICATION

This application claims the priority benefit of Taiwan application serial no. 96130855, filed on Aug. 21, 2007. The entirety of the above-mentioned patent application is hereby incorporated by reference herein and made a part of this specification.

### BACKGROUND OF THE INVENTION

1. Field of the Invention

The present invention generally relates to a method for fabricating a pixel structure, in particular, to a method for fabricating a pixel structure through a laser ablation process.

2. Description of Related Art

Displays are served as communication interfaces between human and machines, and presently flat panel displays are the mainstream of displays. Flat panel displays can be categorized into organic electroluminescence displays, plasma display panels, and thin film transistor liquid crystal displays (TFT-LCDs), wherein TFT-LCDs are the most widely adopted flat panel displays. Generally speaking, a TFT-LCD includes a TFT array substrate, a color filter substrate, and a liquid crystal layer. The TFT array substrate includes a plurality of scan lines, a plurality of data lines, and a plurality of pixel structures arranged in array, wherein each of the pixel structures is electrically connected to a corresponding scan line and a corresponding data line, respectively.

FIGS. 1A˜1G are diagrams illustrating a conventional method for fabricating a pixel structure. Referring to FIG. 1A, a substrate 10 is provided, and a gate 20 is formed on the substrate 10 through a first photolithography and etching process (PEP). Then, referring to FIG. 1B, a gate dielectric layer 30 is formed on the substrate 10 to cover the gate 20. Next, referring to FIG. 1C, a channel layer 40 located above the gate 20 is formed on the gate dielectric layer 30 through a second photolithography and etching process. Generally speaking, the material of the channel layer 40 is amorphous silicon. After that, referring to FIG. ID, a source 50 and a drain 60 are respectively formed on a part of the channel layer 40 and on a part of the gate dielectric layer 30 through a third photolithography and etching process. As shown in FIG. 1D, the source 50 and the drain 60 are respectively extended from both sides of the channel layer 40 onto the gate dielectric layer 30 and expose a part of the channel layer 40. Next, referring to FIG. 1E, a passivation layer 70 is formed on the substrate 10 to cover the gate dielectric layer 30, the channel layer 40, the source 50, and the drain 60. Then referring to FIG. 1F, the passivation layer 70 is patterned through a fourth photolithography and etching process, so as to form a contact hole H in the passivation layer 70. As shown in FIG. 1F, the contact hole H formed in the passivation layer 70 exposes a part of the drain 60. Next, referring to FIG. 1G, a pixel electrode 80 is formed on the passivation layer 70 through the fifth photolithography and etching process. As shown in FIG. 1G, the pixel electrode 80 is electrically connected to the drain 60 through the contact hole H. The fabrication of a pixel structure 90 is accomplished when the pixel electrode 80 has been formed.

As described above, it requires five photolithography and etching processes to fabricate the conventional pixel structure 90. In other words, five photo-masks having different patterns are used for fabricating the pixel structure 90. Because the fabrication cost of photo-masks is quite high, the fabrication cost of the pixel structure 90 cannot be reduced when the number of photolithography and etching processes is not decreased.

Besides, the size of photo-masks for fabricating a TFT array substrate increases along with the increase in the size of a TFT-LCD panel, and the fabrication cost of the large-sized photo-masks is even higher, thus, the fabrication cost of the pixel structure 90 cannot be reduced.

### SUMMARY OF THE INVENTION

Accordingly, the present invention is directed to a method for fabricating a pixel structure which is capable of reducing fabrication cost.

The present invention provides a method for fabricating a pixel structure. First, a substrate is provided, and a gate is formed on the substrate. Next, a gate dielectric layer is formed on the substrate to cover the gate. After that, a semiconductor layer is formed on the gate dielectric layer. Then, a first shadow mask is provided above the semiconductor layer, and the first shadow mask exposes parts of the semiconductor layer. Next, a laser is irradiated on the semiconductor layer through the first shadow mask, so as to remove the parts of the semiconductor layer exposed by the first shadow mask and form a channel layer. After that, a source and a drain are formed on the channel layer at both sides of the gate, wherein the gate, the channel layer, the source, and the drain form a thin film transistor (TFT). Then, a patterned passivation layer is formed on the TFT to cover the channel layer and expose the drain. Thereafter, a conductive layer is formed to cover the patterned passivation layer and the drain, and the conductive layer is automatically patterned by the patterned passivation layer so as to form a pixel electrode.

According to an embodiment of the present invention, after forming the patterned passivation layer, the patterned passivation layer is further baked, such that the patterned passivation layer has a mushroom-shaped top surface, wherein the mushroom-shaped top surface of the patterned passivation layer is greater than the bottom surface thereof.

According to an embodiment of the present invention, the method for forming the gate may include following steps. First, a first metal layer is formed on a substrate, and then the first metal layer is patterned to form the gate. According to another embodiment of the present invention, the method for forming the gate may include following steps. First, a first metal layer is formed on a substrate. Then, a second shadow mask is provided above the first metal layer, and the second shadow mask exposes parts of the first metal layer. Next, a laser is irradiated on the first metal layer through the second shadow mask, so as to remove the parts of the first metal layer exposed by the second shadow mask.

According to an embodiment of the present invention, the method for forming the source and the drain may include following steps. First, a second metal layer is formed on the channel layer and the gate dielectric layer, and the second metal layer is then patterned to form the source and the drain.

According to an embodiment of the present invention, the patterned passivation layer may be further formed on a part of the gate dielectric layer.

According to an embodiment of the present invention, the method for forming the patterned passivation layer may include following steps. First, a passivation layer is formed on the gate dielectric layer and the TFT after the TFT is formed. Next, the passivation layer is patterned to form the patterned passivation layer. According to another embodiment of the present invention, the method for forming the patterned passivation layer may include following steps. First, a passivation layer is formed on the gate dielectric layer and the TFT after the TFT is formed. Next, a third shadow mask is provided above the passivation layer, and the third shadow mask exposes parts of the passivation layer. After that, a laser is irradiated on the passivation layer through the third shadow mask to remove the parts of the passivation layer exposed by the third shadow mask.

According to an embodiment of the present invention, the method for forming the conductive layer includes sputtering an indium tin oxide (ITO) layer or an indium zinc oxide (IZO) layer.

According to an embodiment of the present invention, the power of the laser irradiated on the semiconductor layer may be between about 10 mJ/cm² and about 500 mJ/cm², and the wavelength of the laser may be between about 100 nm and about 400 nm.

According to an embodiment of the present invention, the mushroom-shaped top surface of the patterned passivation layer may be greater than the bottom surface thereof.

According to an embodiment of the present invention, the method further includes removing the patterned passivation layer after the pixel electrode is formed.

According to an embodiment of the present invention, the method further includes forming a capacitor-bottom electrode while the gate is formed and forming a capacitor-top electrode while the source and the drain are formed, wherein the capacitor-bottom electrode and the capacitor-top electrode form a storage capacitor.

In the present invention, the conductive layer is automatically patterned to form the pixel electrode through the patterned passivation layer at the same time when the conductive layer is formed. Thus, compared to the conventional technique, the fabrication method in the present invention provides a simplified fabrication process and reduced fabrication cost. Moreover, while forming the semiconductor layer, the shadow mask used in the laser ablation process is simpler than the masks used in the conventional technique, and therefore, the fabrication cost of the shadow mask in the laser ablation process is much lower.

### BRIEF DESCRIPTION OF THE DRAWINGS

The accompanying drawings are included to provide a further understanding of the invention, and are incorporated in and constitute a part of this specification. The drawings illustrate embodiments of the invention and, together with the description, serve to explain the principles of the invention.

FIGS. 1A˜1G are diagrams illustrating a conventional method for fabricating a pixel structure.

FIGS. 2A˜2G are diagrams illustrating a method for fabricating a pixel structure according to an embodiment of the present invention.

FIGS. 3A˜3C are diagrams illustrating a laser ablation process for forming a gate.

FIGS. 4A˜4C are diagrams illustrating a method for forming a source and a drain.

FIGS. 5A˜5C are diagrams illustrating a method for forming a patterned passivation layer.

FIGS. 6A˜6H are diagrams illustrating a method for fabricating a pixel structure according to another embodiment of the present invention.

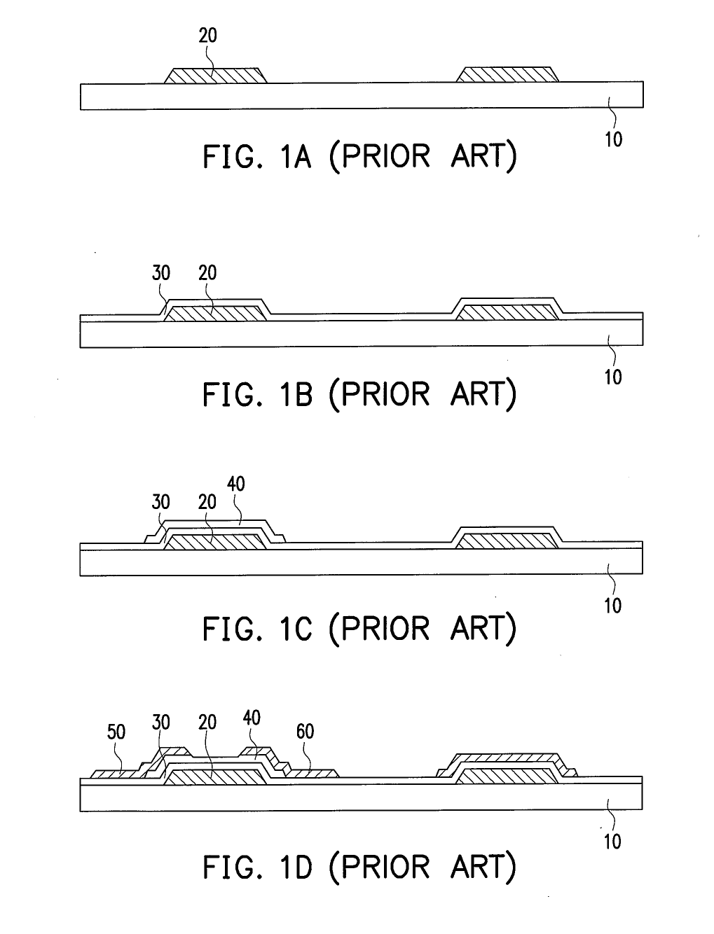

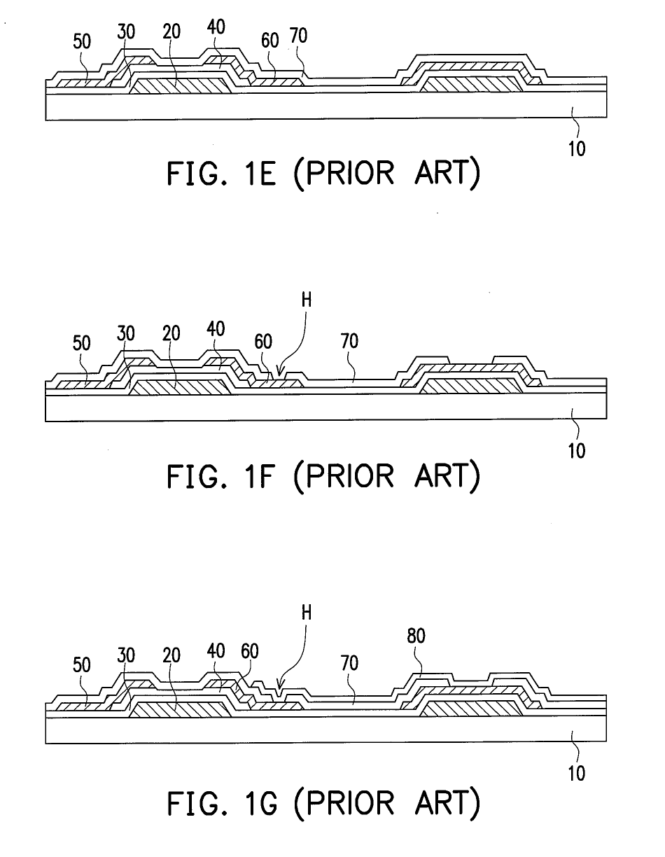

### DESCRIPTION OF THE EMBODIMENTS

Reference will now be made in detail to the present preferred embodiments of the invention, examples of which are illustrated in the accompanying drawings. Wherever possible, the same reference numbers are used in the drawings and the description to refer to the same or like parts.

### First Embodiment

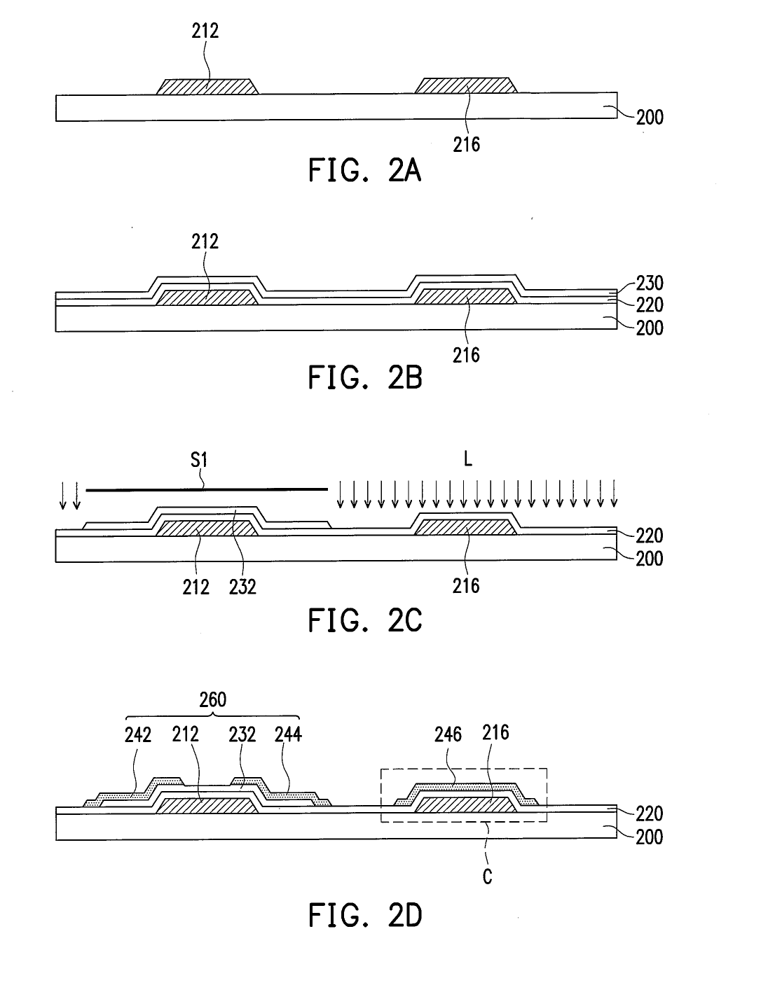

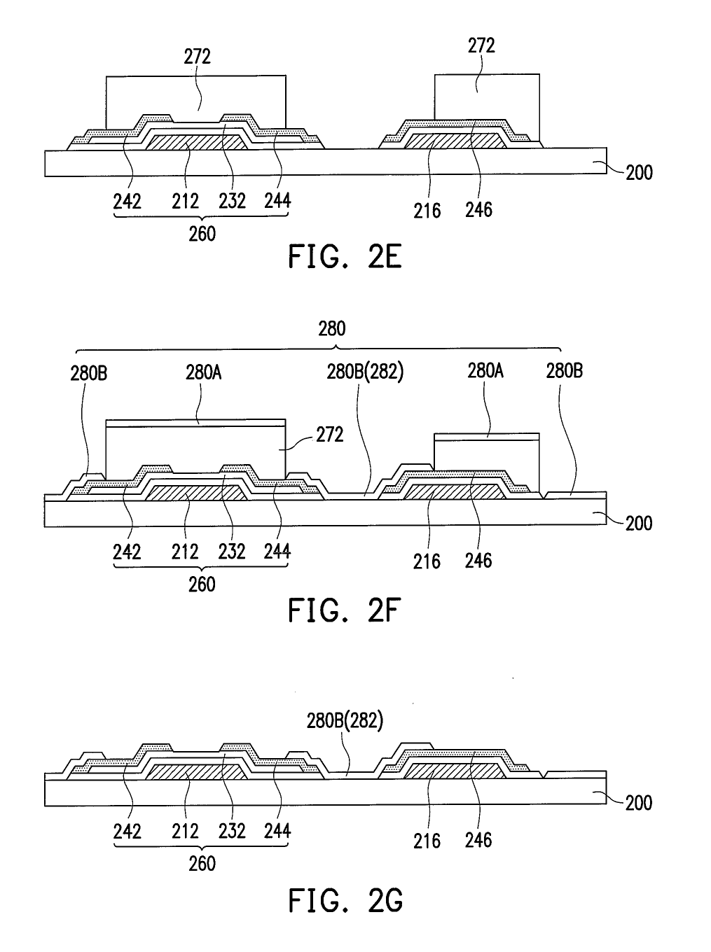

FIGS. 2A˜2G are diagrams illustrating a method for fabricating a pixel structure according to the first embodiment of the present invention. Referring to FIG. 2A, a substrate 200 is provided, wherein the material of the substrate 200 may be a rigid material (e.g. glass) or a flexible material (e.g. plastic). Next, a gate 212 is formed on the substrate 200. In the present embodiment, a capacitor-bottom electrode 216 is further formed while forming the gate 212. Specifically, the capacitor-bottom electrode 216 and the gate 212 are formed simultaneously through the same photolithography and etching process.

Referring to FIG. 2B, a gate dielectric layer 220 is formed on the substrate 200 to cover the gate 212 and the capacitor-bottom electrode 216, wherein the gate dielectric layer 220 may be formed by chemical vapor deposition (CVD) process or other suitable thin film deposition processes, and the gate dielectric layer 220 may be made of a dielectric material, such as silicon oxide, silicon nitride, or silicon-oxy-nitride. After that, a semiconductor layer 230 is formed on the gate dielectric layer 220. In the present embodiment, the material of the semiconductor layer 230 may be amorphous silicon or other semiconductor materials.

Referring to FIG. 2C, a first shadow mask S1 is provided above the semiconductor layer 230, and the first shadow mask S1 exposes parts of the semiconductor layer 230. Next, a laser L is irradiated on the semiconductor layer 230 through the first shadow mask S1, so as to remove the parts of the semiconductor layer 230 exposed by the first shadow mask S1 and thus form a channel layer 232. Specifically, the semiconductor layer 230 radiated by the laser L absorbs the power of the laser L and is ablated from the surface of the gate dielectric layer 220, and the part of the semiconductor layer 230 covered by the first shadow mask S1 remains to form a channel layer 232. Preferably, the power of the laser L for ablating the semiconductor layer 230 may be between about 10 mJ/cm² and about 500 mJ/cm², and the wavelength of the laser L may be between about 100 nm and about 400 nm. Since the semiconductor layer 230 absorbs the laser L and is ablated accordingly while the gate dielectric layer 220 under the semiconductor layer 230 does not absorb the laser L, the surface of the gate dielectric layer 220 will not be damaged. Thus, the storage capacitor can have better charge storage performance and accordingly a better display quality can be achieved compared to the conventional etching technique.

Referring to FIG. 2D, a source 242 and a drain 244 are respectively formed on the channel layer 232 at both sides of the gate 212, wherein the gate 212, the channel layer 232, the source 242, and the drain 244 form a thin film transistor (TFT) 260. In another embodiment of the present invention, an ohmic contact layer (not shown) may be formed on the surface of the semiconductor layer 230 (as illustrated in FIG. 2B) first, and then parts of the ohmic contact layer are removed by an etching process. For example, an N-doped region (i.e. the ohmic contact layer) may be formed on the surface of the semiconductor layer 230 through ion implant, so as to reduce the contact resistance between the channel layer 232 and the source 242 and the contact resistance between the channel layer 232 and the drain 244. Besides, in the present embodiment, a capacitor-top electrode 246 is further formed while forming the source 242 and the drain 244, as shown in FIG. 2D. Specifically, the capacitor-top electrode 246, the source 242 and the drain 244 are formed simultaneously through the same photolithography and etching process. The capacitor-bottom electrode 216 and the capacitor-top electrode 246 form a storage capacitor C for maintaining display quality.

Referring to FIG. 2E, a patterned passivation layer 272 is formed on the TFT 260 to cover the channel layer 232 and expose the drain 244. As shown in FIG. 2E, in the present embodiment, the patterned passivation layer 272 may be further formed on a part of the gate dielectric layer 220. The patterned passivation layer 272 may be made of an organic material, such as acrylic resin or photosensitive resin, or an inorganic dielectric material, such as silicon oxide, silicon nitride, or silicon-oxy-nitride. Additionally, the patterned passivation layer 272 may be formed by photoresist coating process or other suitable thin film deposition processes, such as CVD process. In FIG. 2E, an etching process is performed. During the etching process, the patterned passivation layer 272 and a second metal layer 240 are as a hard mask to remove parts of the gate dielectric layer 220 and expose the first metal layer 210 (not shown) on the gate pads (not shown).

Referring to FIG. 2F, a conductive layer 280 is formed to cover the patterned passivation layer 272 and the drain 244, wherein the conductive layer 280 may be formed by sputtering an indium tin oxide (ITO) layer or an indium zinc oxide (IZO) layer. The patterned passivation layer 272 below the conductive layer 280 has an appropriate thickness, such that two conductive layers 280A and 280B which are electrically insulated from each other are automatically formed when the conductive layer 280 is formed. Specifically, by appropriately adjusting the thickness of the patterned passivation layer 272 and utilizing the anisotropic characteristic of the thin film deposition process for forming the conductive layer 280, two separate conductive layers 280A and 280B can be formed on the conductive layer 280 due to the thickness drop of the patterned passivation layer 272. The conductive layer 280A is formed on the top surface of the patterned passivation layer 272, while the conductive layer 280B is formed on the substrate 200 and the drain 244, wherein a part of the conductive layer 280B connected to the drain 244 forms a pixel electrode 282. It should be noted that the conductive layer 280 in the present embodiment is automatically patterned to form the pixel electrode 282 through the patterned passivation layer 272 at the same time when the conductive layer 280 is formed. Therefore, the number of photolithography and etching processes is reduced and the fabrication process is simplified.

Generally, the patterned passivation layer 272 can be removed after the pixel electrode 282 is formed, as shown in FIG. 2G. The patterned passivation layer 272 may be removed by applying a stripper on the surfaces of the patterned passivation layer 272 and the conductive layer 280, so that the bottom surface of the patterned passivation layer 272 can be ablated from the surface of the TFT 260 and the surface of the gate dielectric layer 220.

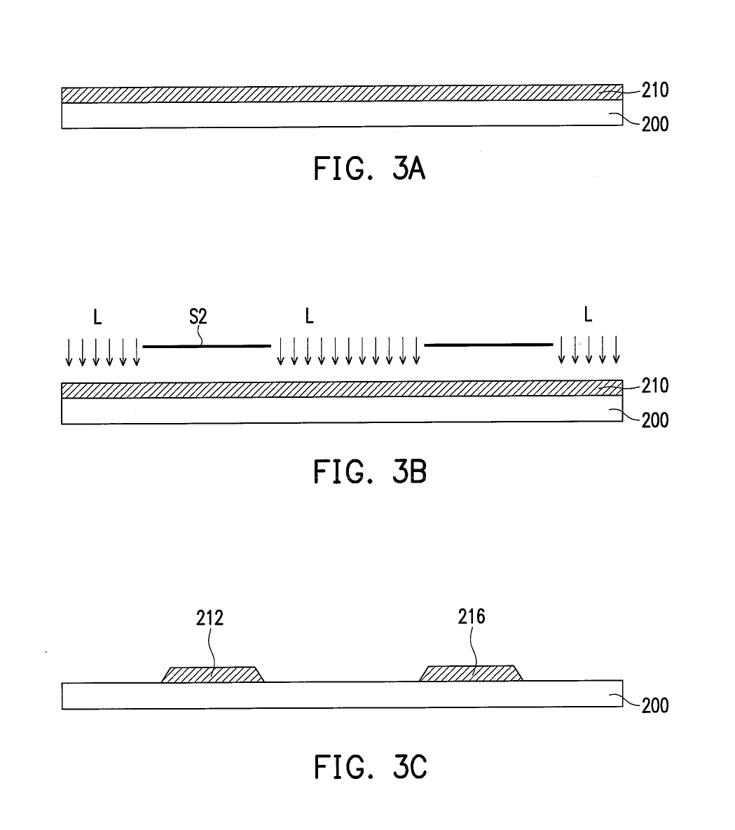

Additionally, the gate 212 may be formed by a laser ablation process. FIGS. 3A˜3C are diagrams illustrating a laser ablation process for forming a gate. Referring to FIG. 3A, a first metal layer 210 is formed on a substrate 200. Referring to FIG. 3B, a second shadow mask S2 is then provided above the first metal layer 210, and the second shadow mask S2 exposes parts of the first metal layer 210. Next, a laser L is irradiated to the first metal layer 210 through the second shadow mask S2 to remove the parts of the first metal layer 210 exposed by the second shadow mask S2. Ultimately, as shown in FIG. 3C, the remaining first metal layer 210 forms a gate 212 and a capacitor-bottom electrode 216. In another embodiment of the present invention, the method for forming the gate 212 may include following steps. First, a first metal layer 210 is formed on a substrate 200. Then, the first metal layer 210 is patterned to form a gate 212 and a capacitor-bottom electrode 216. The first metal layer 210 may be formed by sputtering, evaporation, or other thin film deposition processes, and the first metal layer 210 may be patterned by a photolithography and etching process.

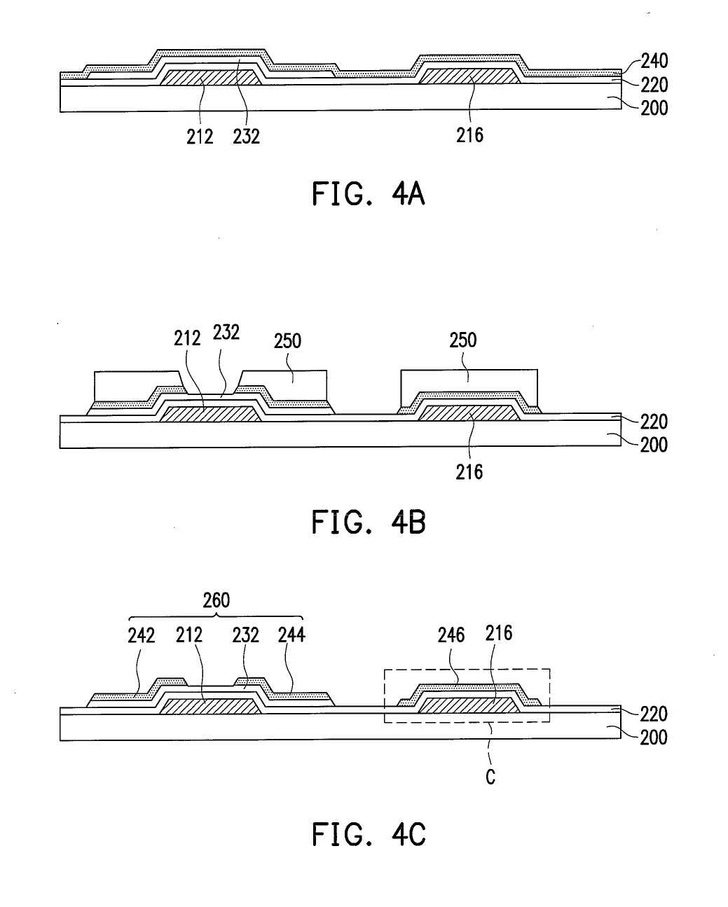

FIGS. 4A˜4C are diagrams illustrating a method for forming the source 242 and the drain 244. Referring to FIG. 4A, a second metal layer 240 is formed on the channel layer 232 and the gate dielectric layer 220. Referring to FIG. 4B, the second metal layer 240 is then patterned. Specifically, a photoresist layer 250 is formed on the channel layer 232 at both sides of the gate 212, and an etching process is performed. During the etching process, the photoresist layer 250 is used as a mask to remove the part of the second metal layer 240 which is not covered by the photoresist layer 250. After removing the photoresist layer 250, as shown in FIG. 4C, a source 242 and a drain 244 are formed on the channel layer 232 at both sides of the gate 212, respectively. In the present embodiment, the photoresist layer 250 may also be formed on the second metal layer 240 above the capacitor-bottom electrode 216 to form a capacitor-top electrode 246 after the etching process is performed, so that the capacitor-top electrode 246 and the capacitor-bottom electrode 216 form a storage capacitor C. The material of the second metal layer 240 may be Al (aluminium), Mo (molybdenum), Ti (titanium), Nd (neodymium), or a nitride containing aforesaid element such as MoN (molybdenum nitride), TiN (titanium nitride), a stack layer of aforesaid elements, an alloy of aforesaid elements, or other conductive materials. In the present embodiment, the etching process may be a wet etching process, while in other embodiments of the present invention, the etching process may also be a dry etching process. In addition, the photoresist layer 250 may be formed by a wet etching process.

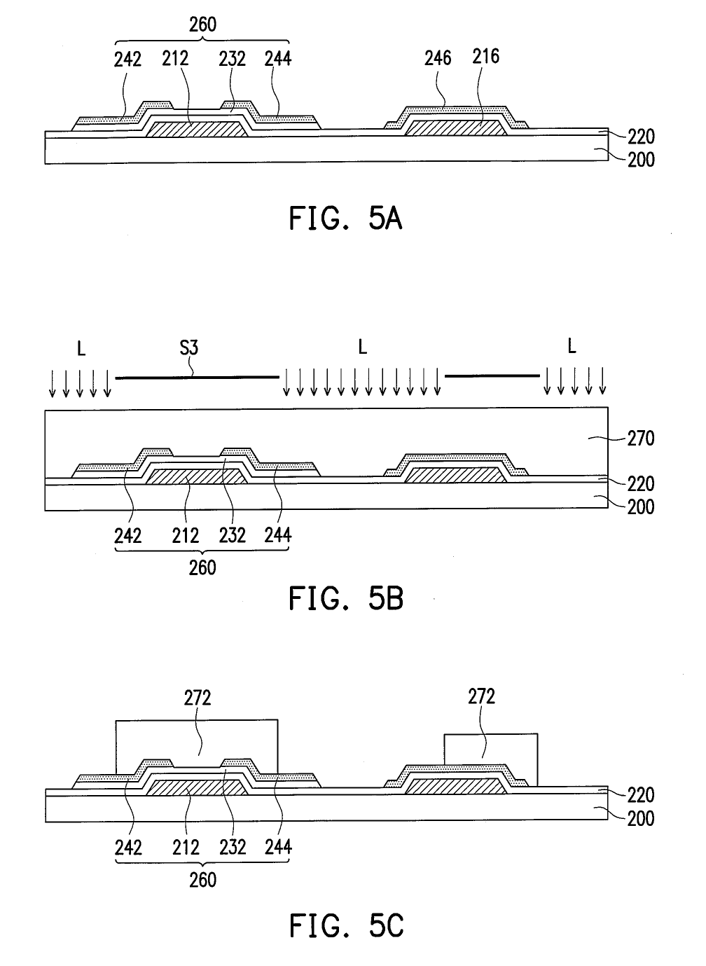

The method for forming the patterned passivation layer 272 may include following steps. First, a passivation layer 270 is formed on the gate dielectric layer 220 and the TFT 260 after forming the TFT 260. Then, the passivation layer 270 is patterned, and the passivation layer 270 may be patterned by a photolithography and etching process. The patterned passivation layer 272 may also be formed by a laser ablation process. FIGS. 5A˜5C are diagrams illustrating a laser ablation process for forming a patterned passivation layer. Referring to FIG. 5A, a passivation layer 270 is formed on the gate dielectric layer 220 and the TFT 260 after the TFT 260 is formed, and a third shadow mask S3 is provided above the passivation layer 270, wherein the third shadow mask S3 exposes parts of the passivation layer 270, as shown in FIG. 5B. After that, a laser L is irradiated to the passivation layer 270 through the third shadow mask S3 to remove the parts of the passivation layer 270 exposed by the third shadow mask S3. Ultimately, as shown in FIG. 5C, the patterned passivation layer 272 is formed.

### Second Embodiment

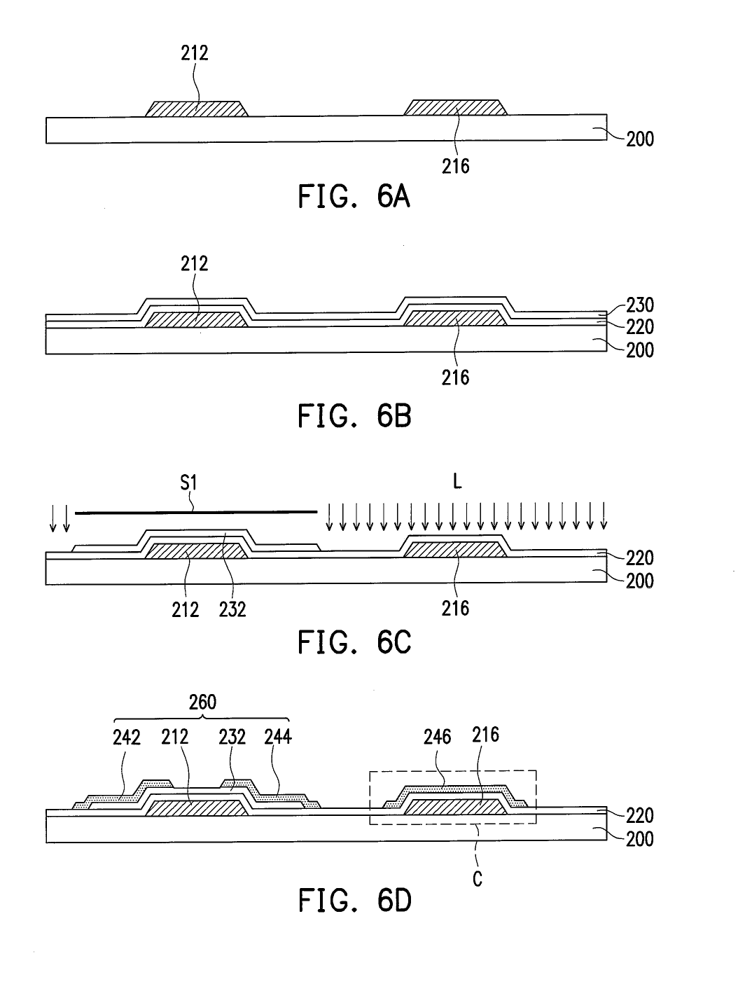

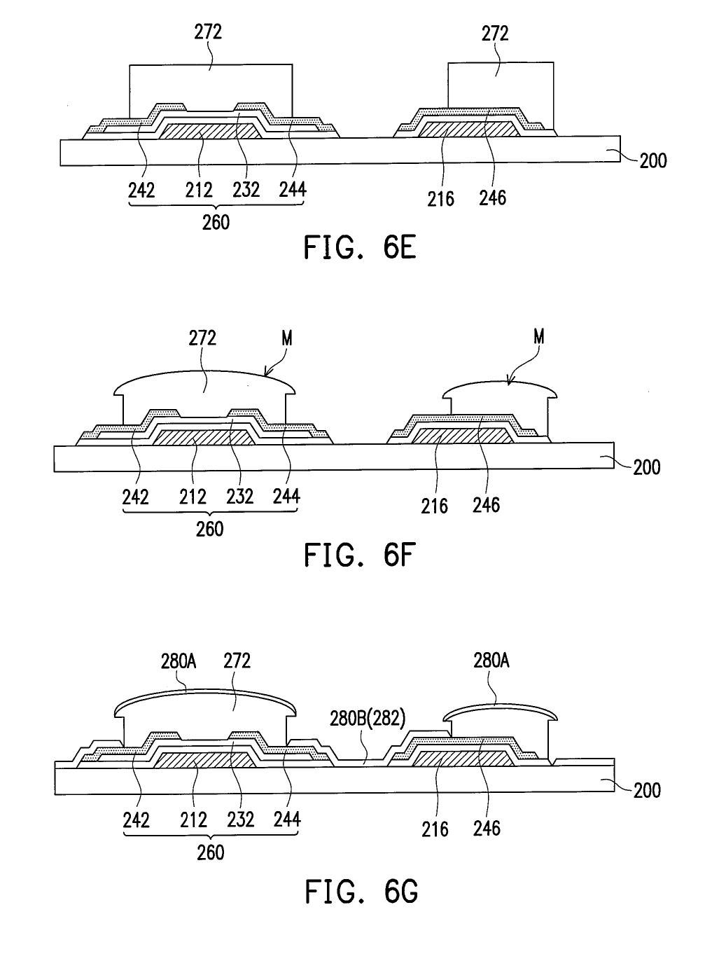

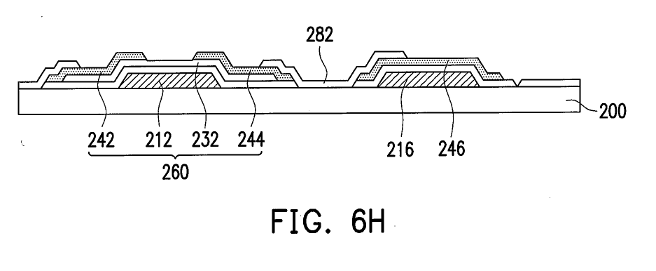

FIGS. 6A˜6H are diagrams illustrating a method for fabricating a pixel structure according to the second embodiment of the present invention. The steps illustrated in FIGS. 6A˜6E are similar to those illustrated in FIGS. 2A˜2E and will not be described herein.

Referring to FIG. 6F, after the patterned passivation layer 272 is formed, the patterned passivation layer 272 is further baked, such that the patterned passivation layer 272 has a mushroom-shaped top surface M. The top surface of the baked patterned passivation layer 272 is greater than the bottom surface thereof so that the top surface of the patterned passivation layer 272 substantially presents the mushroom-shaped top surface M. It should be noted that some process errors, such as temperature, heating speed, and heating time etc, of the baking process has to be considered, and the shape of the patterned passivation layer 272 may vary along with the process errors but will always present a mushroom shape with the top surface thereof greater than the bottom surface thereof. However, the shape of the top surface of the patterned passivation layer 272 is not limited in the present invention.

Referring to FIG. 6G, a conductive layer 280 is formed to cover the patterned passivation layer 272 and the drain 244, wherein the conductive layer 280 may be formed by sputtering an ITO layer or an IZO layer. Since the patterned passivation layer 272 has a mushroom-shaped top surface M which is greater than the bottom surface thereof, two conductive layers 280A and 280B electrically insulated from each other are automatically formed while forming the conductive layer 280. The conductive layer 280A is formed on the patterned passivation layer 272, and the conductive layer 280B is formed on the substrate 200 and the drain 244. A part of the conductive layer 280B connected to the drain 244 forms a pixel electrode 282. It should be noted that, the conductive layer 280 in the present embodiment is patterned to form the pixel electrode 282 through the mushroom-shaped top surface M of the patterned passivation layer 272 at the same time when the conductive layer 280 is formed. Therefore, the number of photolithography and etching processes is reduced and the fabrication process is simplified.

Generally, the patterned passivation layer 272 may be removed after the pixel electrode 282 is formed, as shown in FIG. 6H. The patterned passivation layer 272 may be removed by applying a stripper on the surfaces of the patterned passivation layer 272 and the conductive layer 280, so that the bottom surface of the patterned passivation layer 272 can be ablated from the surface of the TFT 260 and the surface of the gate dielectric layer 220.

In the present invention, the conductive layer is directly patterned (so as to form the pixel electrode) through a patterned passivation layer having an appropriate profile at the same time when the conductive layer is formed. Thus, compared to the conventional technique, the present invention provides a simpler fabrication process. Moreover, in the present invention, the semiconductor layer is formed through a laser ablation process. Thus, compared to the conventional photolithography and etching process, the method for fabricating a pixel structure in the present invention has at least following advantages.

In the present invention, less photolithography process is required for fabricating the pixel structure, and therefore, the fabrication cost of the photo-masks used in the lithography process can be saved.

Since a simpler process is used for fabricating the pixel structure, defects which may be produced during the complicated photolithography and etching process (for example, photoresist coating, soft baking, hard baking, exposure, development, etching, and photoresist ablation etc) can be avoided.

The laser ablation process performed for ablating parts of the semiconductor layer can be applied to pixel electrode repair process to remove ITO residue. Accordingly, the short circuit problem between pixel electrodes can be resolved and the production yield of the pixel structure can be increased.

It will be apparent to those skilled in the art that various modifications and variations can be made to the structure of the present invention without departing from the scope or spirit of the invention. In view of the foregoing, it is intended that the present invention cover modifications and variations of this invention provided they fall within the scope of the following claims and their equivalents.

What is claimed is:

1. A method for fabricating a pixel structure, comprising:
providing a substrate;
forming a gate on the substrate;
forming a gate dielectric layer on the substrate to cover the gate;
forming a semiconductor layer on the gate dielectric layer;
providing a first shadow mask above the semiconductor layer, wherein the first shadow mask exposes parts of the semiconductor layer;
irradiating a laser on the semiconductor layer through the first shadow mask to remove the parts of the semiconductor layer exposed by the first shadow mask and form a channel layer;
forming a source and a drain on the channel layer at both sides of the gate, wherein the gate, the channel layer, the source, and the drain form a thin film transistor (TFT);
forming a patterned passivation layer on the TFT to cover the channel layer and expose the drain; and
forming a conductive layer to cover the patterned passivation layer and the drain, wherein the conductive layer is automatically patterned by the patterned passivation layer to form a pixel electrode.

2. The method according to claim 1, further comprising baking the patterned passivation layer after the patterned passivation layer is formed, such that the patterned passivation layer has a mushroom-shaped top surface.

3. The method according to claim 2, wherein the mushroom-shaped top surface of the patterned passivation layer is greater than the bottom surface of the patterned passivation layer.

4. The method according to claim 1, further comprising removing the patterned passivation layer after the pixel electrode is formed.

5. The method according to claim 1, wherein a method for forming the gate comprises:
forming a first metal layer on the substrate; and
patterning the first metal layer to form the gate.

6. The method according to claim 1, wherein a method for forming the gate comprises:
forming a first metal layer on the substrate;
providing a second shadow mask above the first metal layer, wherein the second shadow mask exposes parts of the first metal layer; and
irradiating a laser on the first metal layer through the second shadow mask to remove the parts of the first metal layer exposed by the second shadow mask.

7. The method according to claim 1, wherein a method for forming the source and the drain comprises:
forming a second metal layer on the channel layer and the gate dielectric layer; and
patterning the second metal layer to form the source and the drain.

8. The method according to claim 1, wherein the patterned passivation layer is formed on a part of the gate dielectric layer.

9. The method according to claim 1, wherein a method for forming the patterned passivation layer comprises:
forming a passivation layer on the gate dielectric layer and the TFT; and
patterning the passivation layer.

10. The method according to claim 1, wherein a method for forming the patterned passivation layer comprises:
forming a passivation layer on the gate dielectric layer and the TFT;
providing a third shadow mask above the passivation layer, wherein the third shadow mask exposes parts of the passivation layer; and
irradiating a laser on the passivation layer through the third shadow mask to remove the parts of the passivation layer exposed by the third shadow mask.

11. The method according to claim 1, wherein a method for forming the conductive layer comprises sputtering an indium tin oxide (ITO) layer or an indium zinc oxide (IZO) layer.

12. The method according to claim 1, wherein a power of the laser is between about 10 mJ/cm² and about 500 mJ/cm².

13. The method according to claim 1, wherein a wavelength of the laser is between about 10 nm and about 400 nm.

14. The method according to claim 1, further comprising:
forming a capacitor-bottom electrode when the gate is formed; and
forming a capacitor-top electrode when the source and the drain are formed,
wherein the capacitor-bottom electrode and the capacitor-top electrode form a storage capacitor.
